(19) United States
(12) Patent Application Publication
(10) Pub. No.: US 2014/0166206 A1
(43) Pub. Date: Jun. 19, 2014

(54) NON-PLASMA DRY ETCHING APPARATUS

(71) Applicant: Panasonic Corporation, Osaka (JP)

(72) Inventors: NAOSHI YAMAGUCHI, Osaka (JP); HIROSHI TANABE, Nara (JP); ICHIRO NAKAYAMA, Osaka (JP)

(73) Assignee: Panasonic Corporation, Osaka (JP)

(21) Appl. No.: 14/073,870

(22) Filed: Nov. 7, 2013

(30) Foreign Application Priority Data
Dec. 13, 2012 (JP) 2012-271950

(51) Int. Cl. H01L 21/67

(52) U.S. Cl. CPC H01L 21/67069
USPC 156/345.33

(57) ABSTRACT

A non-plasma dry etching apparatus is capable of forming textures uniformly only on one side of a silicon substrate. The non-plasma dry etching apparatus includes a stage on which a silicon substrate is placed is used as a base including plural layers. The plural layers include an electrostatic chuck layer, a heat-resistant glass layer and a space layer from the side on which the silicon substrate is placed.

### CROSS REFERENCE TO RELATED APPLICATIONS

This application is entitled and claims the benefit of Japanese Patent Application No. 2012-271950, filed on Dec. 13, 2012, the disclosure of which including the specification, drawings and abstract is incorporated herein by reference in its entirety.

### TECHNICAL FIELD

The technical field relates to a non-plasma dry etching apparatus, and particularly relates to an apparatus forming textures on the surface of a silicon substrate for a solar cell.

### BACKGROUND

As a method of forming textures on the surface of the silicon substrate, a method of wet etching using an alkaline solution and so on has been the mainstream in the past. In recent years, transition to a method of reactive ion etching is proceeding.

On the other hand, as a method of forming textures without using reactive ion etching, a dry etching method in the atmospheric pressure using chlorine trifluoride (ClF3) gas is known (for example, JP-A-10-178194 (Patent Document 1)).

FIG. 13 is a view snowing the dry etching method, in the atmospheric pressure using chlorine trifluoride (ClF3) gas described in Patent Document 1.

In the dry etching method in the same drawing, a stage 2 is provided inside a chamber 1 in the atmospheric pressure, silicon substrates 4 are placed in comb-tooth shape and a given flow amount of ClF3 gas is introduced from a gas cylinder 5 through a mass flow controller 6 to expose the silicon substrates 4 to the ClF3 gas. Such situation causes reaction with respect to silicon only by chemical reaction in the gaseous layer to thereby form textures on the surface of the silicon substrates 4.

Similarly, methods of forming textures on both surfaces of the silicon substrate by using ClF3 gas are described in JP-A-2000-101111 (Patent Document 2) and JP-A-2005-150614 (Patent Document 3) are also known. In these methods, after the dry etching by ClF3 gas, wet etching processing is performed to etch pits with too sharp tips to thereby smooth the surface.

### SUMMARY

However, in a manufacturing apparatus described in Patent Document 1, the etching processing is performed by exposing the silicon substrate in the ClF3 gas atmosphere, which is based on the premise that both surfaces of the substrate are processed. On the other hand, in order to fabricate a back-contact type solar cell by using the silicon substrate with textures, it is necessary to realize the formation of textures only on one side.

The methods of forming textures by dry etching using ClF3 gas described in Patent Documents 2 and 3, include a part in which control of etching reaction is difficult and a part in which the progress of etching reaction is not promoted. Accordingly, there is a problem that distribution occurs in etching inside a substrate surface, and thus uniform, etching is not performed over the entire substrate.

In view of the above-mentioned problems, the present disclosure concerns a non-plasma dry etching apparatus forming textures uniformly only on one side of the substrate as required by a back-contact type solar cell having high power generation efficiency.

In order to solve the above problems, the present inventors fabricated a dry etching apparatus in the vicinity of atmospheric pressure using ClF3 gas, and have studied the formation of textures only on one side.

FIG. 10 is a diagram of an experimental apparatus used at the time of study. A specific structure of the apparatus will be described below.

A stage 2 made of SUS is provided inside a chamber 1. The stage 2 is made of stainless steel, with excellent corrosion resistance. A flow path is provided inside the stage 2 and oil or water is circulated by a chiller 3, which can control the temperature of the stage 2 to be uniform. A silicon substrate 4 is placed on the stage 2. ClF3 gas is supplied to a gas cylinder 5-1, O2 gas is supplied to a gas cylinder 5-2 and N2 gas is supplied to a gas cylinder 5-3 as dilution gas.

The flow amount of these gases is controlled through mass flow controllers 6-1, 6-2 and 6-3 respectively, then, these gases are sprayed, to the surface of the silicon substrate 4 by a shower nozzle 7. At that time, gas inside the chamber 1 is discharged by a blower 10 while being adjusted to a set pressure by a pressure gauge 8 and a pressure regulating valve 9.

A plane-orientation (111) substrate was exposed to mixed gas including ClF3 gas to perform etching processing by using the apparatus. As processing conditions, the temperature of the stage 2 was controlled to 30° C., the pressure inside the chamber 1 was adjusted to 90 kPa and mixed gas including ClF3 gas: 5%, O2 gas: 20% with respect to N2 gas was sprayed.

As a result, as only one side of the substrate was exposed to the gas, the silicon substrate was warped in a concave shape by distortion due to heat as chemical reaction proceeds in the silicon substrate. Then, as the gas flows toward the back surface of the warpage in the silicon substrate, the back surface was etched, and further, chemical reaction occurs also on the front side at the warped position, as a result, the silicon substrate was overheated and melted. On the other hand, at positions on the silicon substrate where the warpage did not occur and remained touching the stage 2, reaction did not progress and etching was not performed, as a result, textures were not formed.

Next, an experimental apparatus as shown in FIG. 11 was constructed.

A bipolar electrostatic adsorption stage 11 in which silver-foil electrode pads were coated with polyimide resin was provided on the stage 2, and the silicon substrate 4 was placed on the bipolar electrostatic adsorption stage 11 to be adsorbed, to thereby prevent warpage of the silicon substrate during etching. In this state, etching processing is performed in the same processing conditions as in the case of the structure shown in FIG. 10.

As a result, chemical reaction of the silicon substrate did not progress and textures were not formed. FIG. 12 shows an electron micrograph of the surface of the plane-orientation (111) substrate after the processing at that time. It can be seen from the micrograph of FIG. 12 that the chemical reaction is not sufficiently promoted and textures are not formed.

Here, a mechanism in which the silicon substrate of plane-orientation (111) is exposed to mixed, gas including ClF3 and O2 to be dry-etched without generating plasma will be described.

The above mechanism is interpreted as the following chemical reaction according to the study made by the present inventors.

3Si+4ClF3→3SiF4↑+2Cl2| (A)

Si+O2→SiO2 (B)

When the silicon substrate is exposed to the ClF3 gas, ClF3 is decomposed and silicon is reacted to be SiF4 as shown in a chemical reaction formula (A). As SiF4 is a gas, it is separated from the silicon substrate. On the other hand, O2 exists in the mixed gas, etching progresses by the chemical reaction (A) as well as SiO2 is microscopically formed according to a chemical reaction (B).

As SiO2 does not react with ClF3 and etching is not performed, the microscopically-formed SiO2 functions as a self mask and etching along the plane orientation is performed based on SiO2. When a surface exposed to the mixed gas is a (111) plane, textures including etching pits surrounded by three planes including a (100) plane, a (010) plane and a (001) plane are formed.

Generally, chemical reaction is promoted by acquiring energy necessary for reaction. In the above case of reaction, an energy source is heat, and a heat source is reaction heat of the chemical reaction (A) and the chemical reaction (B).

Accordingly, in the case of the study made by the structure of FIG. 11, as the silicon substrate 4 closely contacts the stage due to absorbability of the electrostatic adsorption stage 11, heat generated by the chemical reaction (A) and the chemical reaction (B) is radiated from the back surface of the silicon substrate 4 to the stage 2 made of stainless steel of SUS 316 through the electrostatic adsorption stage 11. Then, it is presumable that heat energy which can be used as reaction energy for the chemical reaction (A) and the chemical reaction (B) at a next moment is insufficient.

In the study made by the structure of FIG. 10, the silicon substrate 4 is just placed on the stage 2 without absorbability. Accordingly, at positions where the silicon substrate 4 is warped and floated from the stage 2, it is presumable that heat generated by the chemical reaction (A) and the chemical reaction (B) is used as reaction energy for the chemical reaction (A) and the chemical reaction (B) at a next moment, therefore, excessive reaction has occurred.

In order to solve the above problems, the various embodiments can be characterized in the following three points in the structure of the stage of the dry etching apparatus using the ClF3 gas capable of forming textures only on one side. First, a layer for allowing the silicon substrate to closely contact the stage is provided, in the second place, a layer for accumulating reaction heat is provided, and in the third place, the layer for suppressing the radiation of reaction heat is provided.

The embodiments characterized by the above three points has a mechanism in which the silicon substrate placed on the electrostatic adsorption stage is allowed to closely contact the electrostatic adsorption stage to prevent reaction gas from flowing toward the back surface of the silicon substrate as well as the generated reaction heat being effectively utilized as reaction energy for a next moment according to the above characteristics.

According to the structure, not only the dry etching apparatus using the ClF3 gas capable of forming textures only on one side can be provided but also equipment costs can be suppressed.

When using the dry etching apparatus using the ClF3 gas having the mechanism of the stage according to the various embodiments, the dry etching apparatus capable of manufacturing the substrate on which textures are formed only on one side of the silicon substrate necessary for the back-contact type solar cell can be provided.

### BRIEF DESCRIPTION OF THE DRAWINGS

FIG. 1 is a view showing a dry etching apparatus according to Embodiment 1;

FIG. 2 is an electron micrograph of the surface of a silicon substrate at the time of etching according to Embodiment 1;

FIG. 3 is a view showing a dry etching apparatus according to Embodiment 2;

FIG. 4 is an electron micrograph of the surface of a silicon substrate at the time of etching according to Embodiment 2;

FIG. 5 is a view showing a dry etching apparatus according to Embodiment 3;

FIG. 6 is an enlarged schematic view of a stage portion of the dry etching apparatus according to Embodiment 3;

FIG. 7 is a view showing a dry etching apparatus according to Embodiment 4;

FIGS. 8A-8B are views showing a dry etching apparatus according to Embodiment 5;

FIG. 9 is a view showing the dry etching apparatus according to Embodiment 5;

FIG. 10 shows an experimental apparatus;

FIG. 11 shows an experimental apparatus;

FIG. 12 is an electron micrograph of the surface of a silicon substrate at the time of etching by the experimental apparatus having the structure shown in FIG. 11; and

FIG. 13 is a view showing an apparatus for forming textures as described in Patent Document 1.

### DESCRIPTION OF THE PREFERRED EMBODIMENTS

Hereinafter, various embodiments will be explained with reference to the drawings.

### Embodiment 1

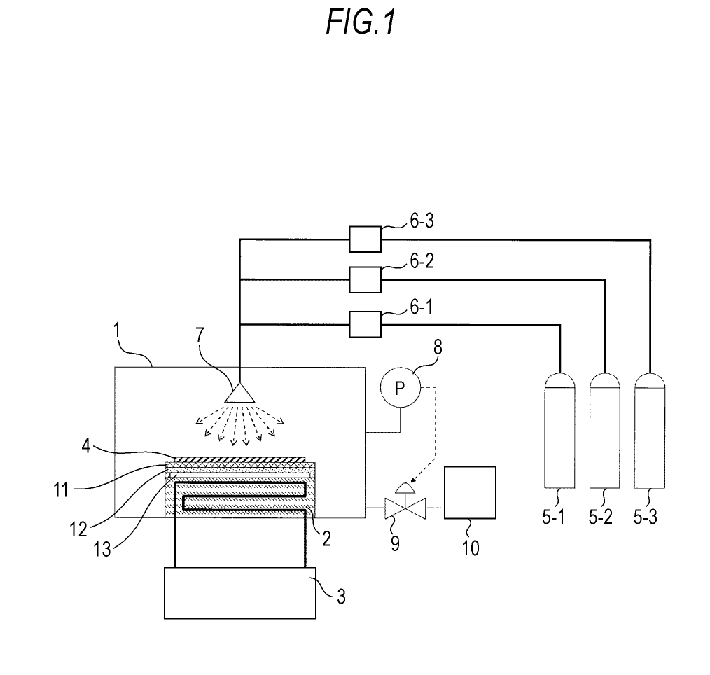

FIG. 1 is a view showing a non-plasma dry etching apparatus according to Embodiment 1.

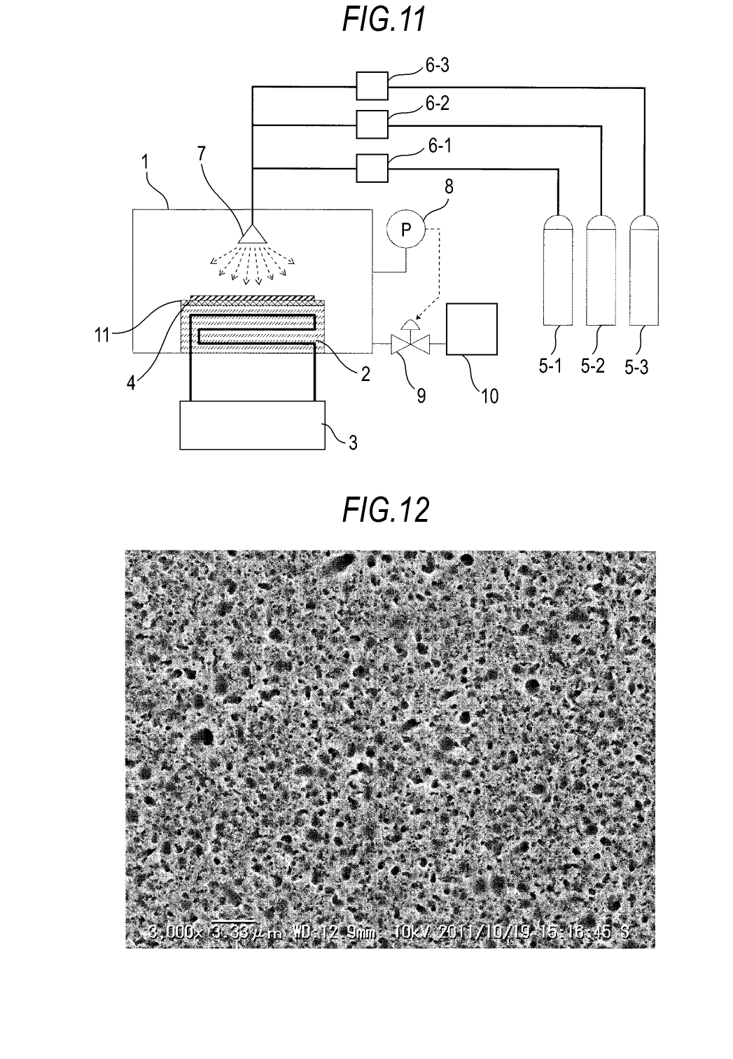

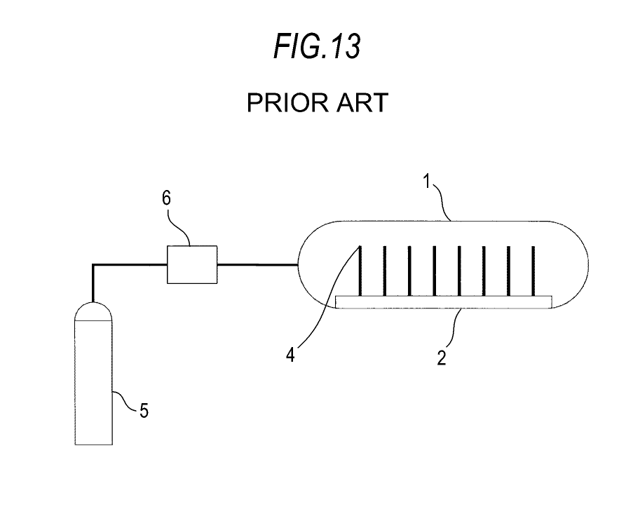

In FIG. 1, the same components as in FIG. 10, FIG. 11 and FIG. 13 are denoted by the same reference numerals and explanation thereof is omitted.

In the present embodiment, a stage 2 made of SUS is provided inside a chamber 1 in the same manner as in the structures of FIG. 10 and FIG. 11. The stage 2 is made of stainless steel with excellent corrosion, resistance. A flow path is provided inside the SUS stage 2 and oil or water is circulated by a chiller 3, which can control the temperature of the stage 2 to be uniform. However, as the stainless steel is a metal and has good thermal conductivity, it is not preferable that the silicon substrate 4 is directly placed thereon because radiation property of reaction heat is high. On the other hand, it is necessary that the silicon substrate 4 is adsorbed to the stage for preventing warpage of the substrate and flow of gas toward the back surface during reaction.

Accordingly, a heat-resistant glass stage 12 is prepared, an electrostatic adsorption stage 11 is bonded on the heat-resistant glass stage 12 and the silicon substrate 4 is placed on the electrostatic adsorption stage 11 to be adsorbed. Furthermore, a gap 13 is provided between the heat-resistant glass stage 12 and the stage 2.

The electrostatic adsorption stage 11 bonded to the heat-resistant glass stage 12 is formed as a layer for allowing the silicon substrate to closely contact the stage, the heat-resistant glass stage 12 is formed as a layer for accumulating reaction heat and the space 13 is formed as a layer for suppressing the radiation of reaction heat.

Here, advantages of Embodiment 1 will be explained. Generally, thermal resistance can be cited as a characteristic indicating low-conductivity of heat. A high value of thermal resistance indicates low-conductivity of heat. A thermal resistance R[K/W] is represented by the following formula when a thermal conductivity is k [W/m·K)], a thickness is L[m] and a surface area is A[m2].

R=L/(k·A) (C)

In the present embodiment, the following values were set and thermal resistance values were calculated based on these values.

In silicon substrate 4, thermal conductivity: k4, thickness: L4, surface area: A4 and thermal resistance value: R4.

In the electrostatic adsorption stage 11, thermal conductivity: k11, thickness: L11, surface area: A11 and thermal resistance value: R11.

In heat-resistant glass stage 12, thermal conductivity: k12, thickness: L12, surface area: A12 and thermal resistance value: R12.

In the space 13, thermal conductivity: k13, thickness: L13, surface area: A13 and thermal resistance value: R13.

In the stage 2, thermal conductivity: k2, thickness: L2, surface area: A2 and thermal resistance value: R2.

A table 1 shows calculated thermal resistance values of the above members.

TABLE 2

| | | | Heat- | | |
|---|---|---|---|---|---|
| | | Electrostatic | resistant | | |
| | Silicon | adsorption | glass | | |
| | substrate 4 | stage 11 | stage 12 | Space 13 | SUS stage 2 |
| Thermal | 149 | 0.16 | 1.2 | 0.026 | 16.7 |
| conductivity κ | | | | | |
| [W/(m · K)] | | | | | |
| Thickness L [m] | 0.16 × 10⁻³ | 0.24 × 10⁻³ | 2.00 × 10⁻³ | 2.00 × 10⁻³ | 8.00 × 10⁻³ |
| Area A [m²] | 15.63 × 10⁻³ | 15.63 × 10⁻³ | 15.63 × 10⁻³ | 15.63 × 10⁻³ | 15.63 × 10⁻³ |
| Thermal | 68.724 × 10⁻⁶ | 0.096 | 0.107 | 4.923 | 0.031 |
| resistance R | | | | | |
| [K/W] | | | | | |

Here, a bipolar electrostatic adsorption stage coated with polyimide is a member including plural stacked films of a polyimide layer, an adhesive layer and an electrode layer. As the electrode layer is negligibly thin and the adhesive layer has a thermal conductivity close to polyimide, the thermal conductivity of the electrostatic adsorption stage 11 is set to the thermal conductivity of polyimide.

Additionally, as the pressure of the chamber 1 before etching processing is adjusted by the N2 gas in advance and active forced convection does not occur in the space 13, conductive heat transfer of the N2 gas is assumed to be performed in the space 13. As the silicon substrate with 125 mm in length×125 mm in width is used, the surface area is assumed to be A4=A11=A12=A13=15.63×10⁻³ [m2].

According to the calculated results, the thermal resistance value R2=0.031 [K/W] of the stage 2 is the lowest value in the components forming the stage, therefore, it can be seen that the stage 2 is the member quickly radiating neat. Moreover, the thermal resistance value R4=68.724×10⁻⁶ [K/W] of the silicon substrate 4 is an extremely low value, which indicates that reaction heat generated on the surface of the silicon substrate 4 immediately transmits to the back surface.

However, the thermal resistance values of the electrostatic adsorption stage 11, the heat-resistant glass stage 12 and the space 13 are respectively R11=0.096 [K/W], R12=0.107 [K/W], R13=4.923 [K/W], and the total thermal resistance value R=0.096+ 0.107+4.923=5.126 [K/W], which is approximately 165 times as large as the thermal resistance value R=0.031 of the stage 2, which indicates that the components of the electrostatic adsorption stage 11, the heat-resistant glass stage 12 and the space 13 block the radiation to the stage 2.

That is, reaction heat generated on the surface of the silicon substrate 4 immediately transmits to the back surface, however, the components of the electrostatic adsorption stage 11, the heat-resistant glass stage 12 and the space 13 block the radiation to the stage 2 and the heat accumulated in the components of the electrostatic adsorption stage 11 and the heat-resistant glass stage 12 is transmitted from the back surface of the substrate and is used as reaction energy for a next chemical reaction.

Additionally, the thermal resistance value R13 is particularly nigh, which indicates that the radiation to the stage 2 can be efficiently suppressed by providing the space layer. Conversely, in the case of the structure of the experimental apparatus as shown in FIG. 11 in which the space layer is not provided on the stage, the only thermal resistance layer between the silicon substrate 4 and the stage 2 is the electrostatic adsorption stage 11. The thermal resistance value R11 of the electrostatic adsorption stage 11 is 0.096 [K/W], which is approximately three times with respect to the thermal resistance value R2=0.031 [K/W] of the SUS stage 2, therefore, it can he seen that reaction heat generated on the surface of the silicon substrate 4 is immediately radiated to the stage 2 as compared with Embodiment 1.

The etching processing of the plane-orientation (111) substrate was performed by using the structure of the present embodiment under conditions in which the temperature of the stage 2 was controlled to 30° C., the ClF3 gas: 5% and the O2 gas: 20% with, respect to the N2 gas as the dilution, gas, and the pressure in the chamber 1 was 98 kPa.

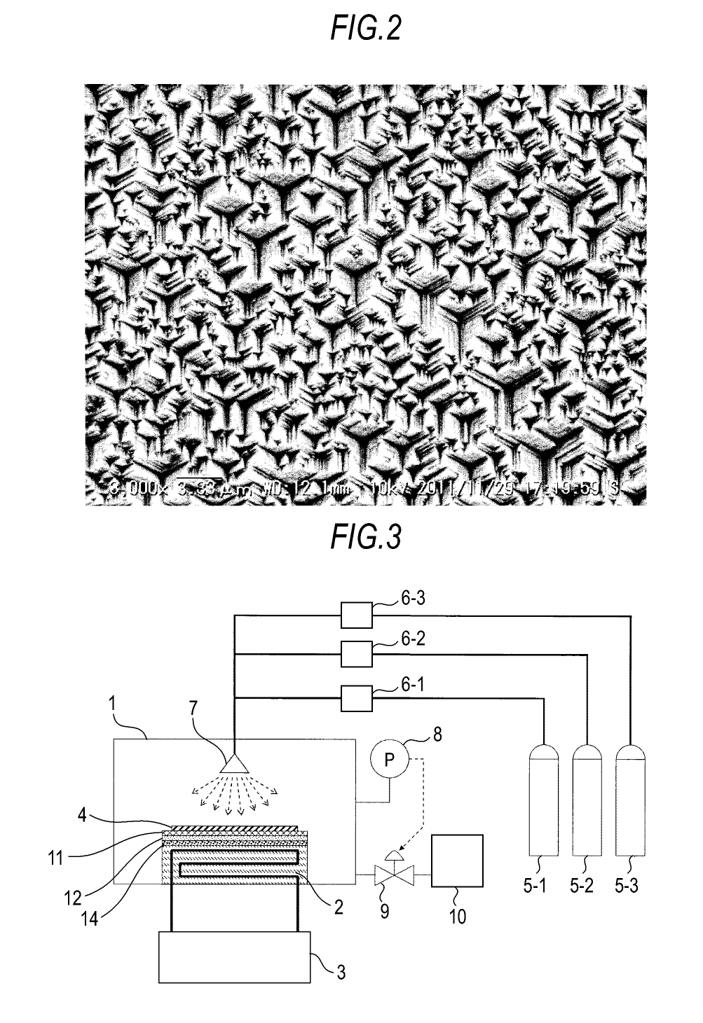

FIG. 2 shows an electron micrograph of the surface of the silicon substrate according to Embodiment 1. Not only the warpage of the substrate due to reaction heat did not occur but also the etching was performed only on the surface exposed to mixed gas including ClF3, O2 and N2, and good textures having etching pits surrounded by three planes of the (100) plane, the (010) plane and the (001) plane were formed.

In the case of the structure of FIG. 11, the temperature on the surface of the silicon substrate was increased to approximately 60° C. at the maximum, whereas in Embodiment 1, the temperature on the surface of the silicon substrate was 30° C. before chemical reaction began, then, the temperature started to increase just after the reaction began and reached approximately 160° C. at the maximum. In the case of Embodiment 1, the components of the electrostatic adsorption stage 11, the heat-resistant glass stage 12 and, the space 13 block the radiation to the stage 2, and heat accumulated in the components of the electrostatic adsorption stage 11 and the heat-resistant glass stage 12 was used as reaction energy of a next chemical reaction.

As described above in Embodiment 1, the electrostatic adsorption stage 11 adhered to the heat-resistant glass stage 12 is formed as the layer for allowing the silicon substrate to closely contact the stage, the heat-resistant glass stage 12 is formed as the layer accumulating reaction heat, and further, the space 13 is formed as the layer suppressing the radiation of reaction heat. When applying the dry etching apparatus using the ClF3 gas and having the mechanism of the stage characterized as the above, the substrate in which textures are formed only on one side of the silicon substrate necessary for the back-contact type solar cell can be manufactured.

### Embodiment 2

FIG. 3 is a view showing a dry etching apparatus according to Embodiment 2.

In the drawing, the same components as in FIG. 1, FIG. 10, FIG. 11 and FIG. 13 are denoted by the same reference numerals and explanation thereof is omitted.

In the present embodiment, the heat-resistant glass stage 12 is prepared, the electrostatic adsorption stage 11 is bonded on the heat-resistant glass stage 12 and the silicon substrate 4 is placed on the electrostatic adsorption stage 11 to be adsorbed. In the present embodiment, a Teflon (registered trademark) stage 14 is formed instead of the space 13 as compared with Embodiment 1.

The electrostatic adsorption stage 11 bonded to the heat-resistant glass stage 12 is formed as a layer for allowing the silicon substrate to closely contact the stage. The heat-resistant glass stage 12 and the Teflon (registered trademark) stage 14 are formed to have both effects of a layer for accumulating reaction neat and a layer for suppressing the radiation of reaction heat.

Here, advantages of the present embodiment will be explained.

In the present embodiment, a thermal conductivity was set to k14, a thickness was set to L14, a surface area was set to A14 and a thermal resistance value was set to R14 in the Teflon (registered trademark) stage 14. Other values were set to the same values as in Embodiment 1.

A table 2 shows calculated thermal resistance values of the above members.

TABLE 2

| | | | Heat- | | |
|---|---|---|---|---|---|
| | | Electrostatic | resistant | | |
| | Silicon | adsorption | glass | Teflon | |
| | substrate 4 | stage 11 | stage 12 | stage 14 | SUS stage 2 |
| Thermal | 149 | 0.16 | 1.2 | 0.25 | 16.7 |
| conductivity κ | | | | | |
| [W/(m · K)] | | | | | |
| Thickness L [m] | 0.16 × 10⁻³ | 0.24 × 10⁻³ | 2.00 × 10⁻³ | 2.00 × 10⁻³ | 8.00 × 10⁻³ |
| Area A [m²] | 15.63 × 10⁻³ | 15.63 × 10⁻³ | 15.63 × 10⁻³ | 15.63 × 10⁻³ | 15.63 × 10⁻³ |
| Thermal | 68.724 × 10⁻⁶ | 0.096 | 0.107 | 0.512 | 0.031 |
| resistance R | | | | | |
| [K/W] | | | | | |

According to the calculated results, the thermal resistance values of the electrostatic adsorption stage 11, the heat-resistant glass stage 12 and the Teflon (registered trademark) stage 14 are respectively R11=0.096 [K/W], R12=0.107 [K/W], R14=0.512 [K/W], and the total thermal resistance value R=0.096+0.107+0.512=0.715 [K/W], which is approximately 23 times as large as the thermal resistance value R2=0.031 of the stage 2, which indicates that the components of the electrostatic adsorption stage 11, the heat-resistant glass stage 12 and the Teflon (registered trademark) stage 14 also have the advantage of sufficiently blocking the radiation to the stage 2, though the thermal resistance value is relatively lower than the value of Embodiment 1.

The etching processing of the plane-orientation (111) substrate was performed by using the structure of the present embodiment under the same conditions as processing conditions in Embodiment 1.

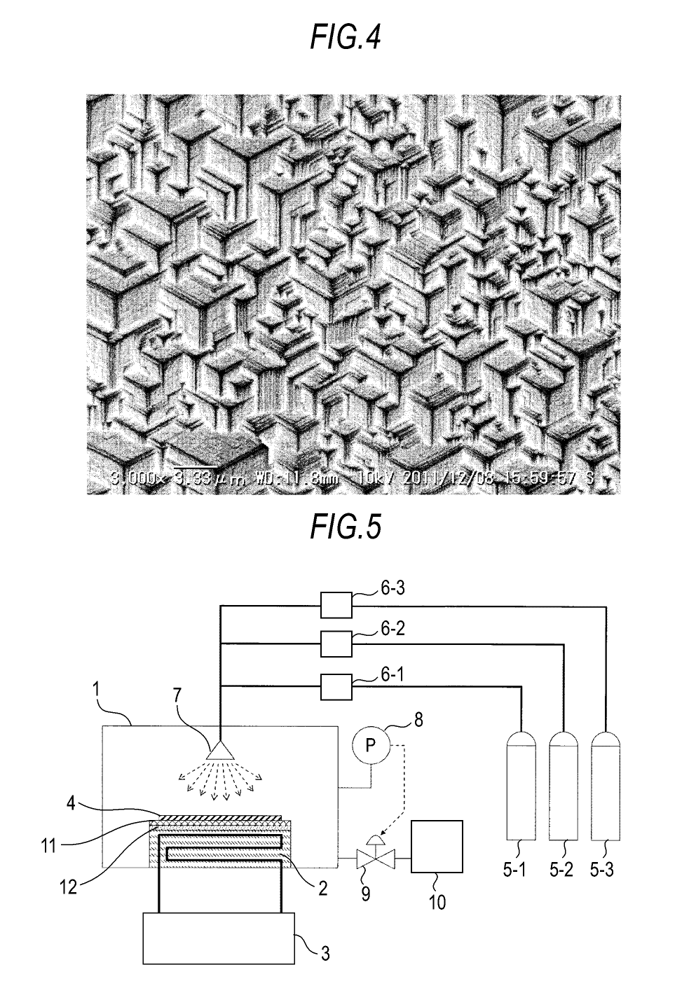

FIG. 4 shows an electron micrograph of the surface of the silicon substrate at that time. Not only the warpage of the substrate due to reaction heat did not occur but also the etching was performed only on the surface exposed, to mixed gas including ClF3, O2 and N2, and good textures having etching pits surrounded by three planes of the (100) plane, the (010) plane and the (001) plane were formed in the same manner as in Embodiment 1.

In the case of the structure of FIG. 11, the temperature on the surface of the silicon substrate was increased to approximately 60° C. at the maximum, whereas in the present embodiment, the temperature on the surface of the silicon substrate was 30° C. before chemical reaction began, then, the temperature started to increase just after the reaction began and reached approximately 120° C. at the maximum. In the case of Embodiment 1, the components of the electrostatic adsorption stage 11, the heat-resistant glass stage 12 and the Teflon (registered trademark) stage 14 block the radiation to the stage 2, and heat accumulated in the components of the electrostatic adsorption stage 11, the heat-resistant glass stage 12 and the Teflon (registered trademark) stage 14 was used as reaction energy of a next chemical reaction.

As described above in Embodiment 2, the electrostatic adsorption stage 11 adhered to the heat-resistant glass stage 12 is formed as the layer for allowing the silicon substrate to closely contact the stage, the heat-resistant glass stage and the Teflon (registered trademark) stage are formed as both elements of the layer accumulating reaction heat and the layer suppressing the radiation of reaction heat. Accordingly, when applying the dry etching apparatus using the ClF3 gas and having the mechanism of the stage characterized as the above, the substrate in which textures are formed only on one side of the silicon substrate necessary for the back-contact type solar cell can be manufactured.

In the case where the total thermal resistance value R of the components positioned above the stage 2 and below the silicon substrate 4 is 0.7 [K/W] or more as in the embodiment, the function of accumulating reaction heat and the function of suppressing the radiation of reaction heat can be sufficiently carried out. Accordingly, the thickness of the heat-resistant glass stage is set to 2 mm and the thickness of the space 13 is 2 mm in Embodiment 1, however, the total thermal resistance value R can satisfy the condition of 0.7 [K/W] or more as long as the thickness L12 of the heat-resistant glass stage 12 is 0.1 mm or more and the thickness L13 of the space 13 is 0.01 mm or more. As it is necessary that the electrostatic adsorption layer is bonded to the heat-resistant glass stage 12 to have the function of holding the silicon substrate 4, the thickness L12 of the heat-resistant glass stage 12 is preferably 0.5 mm or more for securing stiffness.

### Embodiment 3

FIG. 5 is a view showing a dry etching apparatus according to Embodiment 3.

In the drawing, the same components as in FIG. 1, FIG. 3, FIG. 10, FIG. 11 and FIG. 13 are denoted by the same reference numerals and explanation thereof is omitted.

In Embodiment 3, the space 13 as in Embodiment 1 and the Teflon (registered trademark) stage 14 as in Embodiment 2 are not included. The heat-resistant glass stage 12 is prepared, the electrostatic adsorption, stage 11 is bonded on the heat-resistant glass stage 12 and the silicon substrate 4 is placed on the electrostatic adsorption stage 11 to be adsorbed. In the present embodiment, the heat-resistant glass stage 12 is just placed on the stage 2.

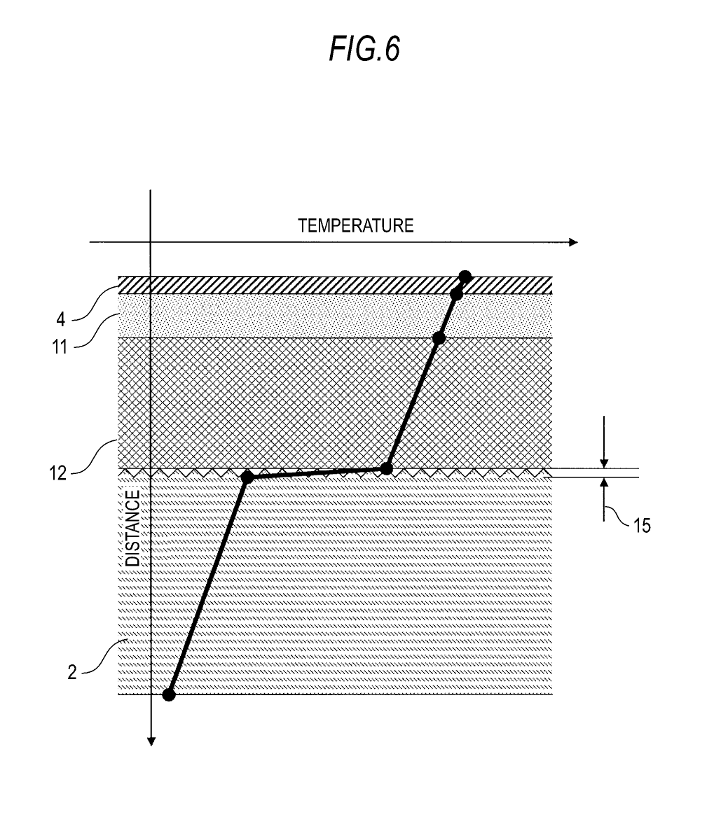

FIG. 6 shows an enlarged schematic view of a stage portion. Temperatures of respective stages are schematically shown by the horizontal axis indicating the temperature of components and by the vertical axis indicating the distance.

Generally, when an object touches an object and conductive heat transfer is performed, fine projections and depressions on surfaces of the objects contact with each other at points, and fine spaces are generated, therefore, a thermal contact resistance layer exists. Also in Embodiment 3, a thermal contact resistance layer 15 is generated between the stage 2 and the heat-resistant glass stage 12 by fine gaps generated by the point contact between the stage 2 and the heat-resistant glass stage 12. As the total thermal resistance value of the electrostatic adsorption stage 11, the heat-resistant glass stage 12 and the thermal contact resistance layer 15 is set to be approximately 0.7 [K/W] or more by utilizing the thermal contact resistance layer 15, the same advantages as in Embodiment 2 can be expected.

That is, the present embodiment is characterized in that the electrostatic adsorption stage 11 bonded to the heat-resistant glass stage 12 is formed as a layer for allowing the silicon substrate to closely contact the stage, the heat-resistant glass stage 12 is formed as a layer for accumulating reaction heat and the thermal contact resistance layer 15 is formed as a layer for suppressing the radiation of reaction neat.

When applying the dry etching apparatus using the ClF3 gas and having the mechanism of the stage characterized as above, the substrate in which textures are formed only on one side of the silicon substrate necessary for the back-contact type solar cell can be manufactured.

As the heat-resistant glass stage is made of glass, surface roughness is negligibly small, and the fine space of the thermal contact resistance layer 15 is almost determined by surface roughness of the stage 2. The advantage can be expected as long as a surface roughness Ra is 6.3 or more when using a notation Ra of the surface roughness specified by JIS. The surface roughness is for securing the fine space and is not limited to the stage 2 side. The roughness may exist on the heat-resistant glass stage side as well as on both sides.

### Embodiment 4

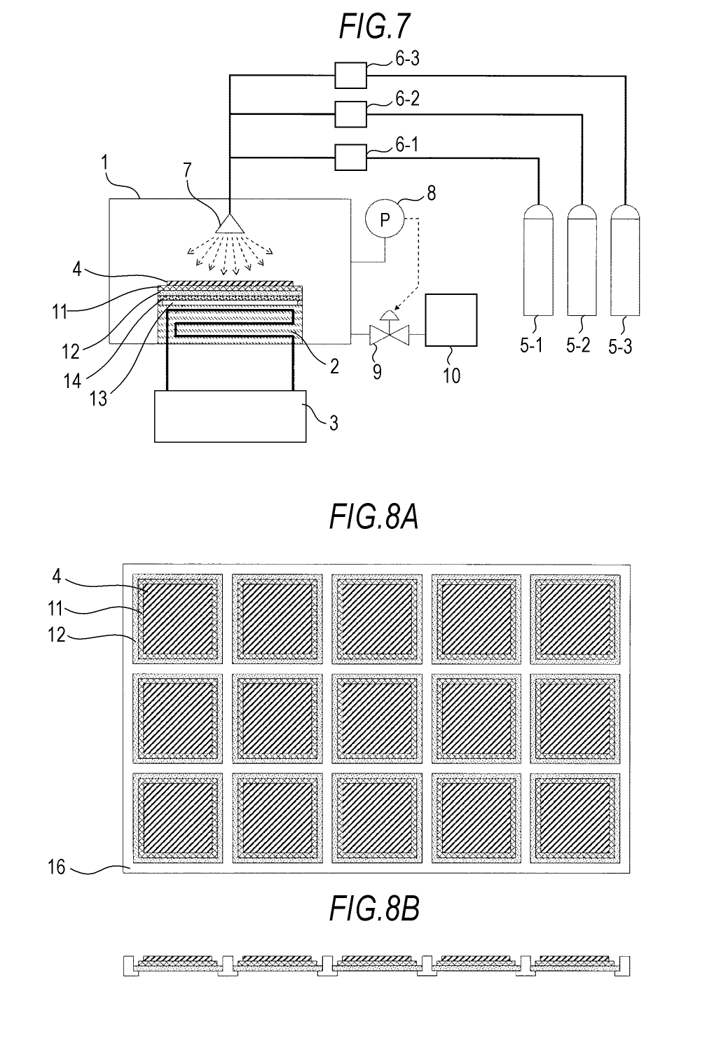

FIG. 7 is a view showing a dry etching apparatus according to Embodiment 4.

In the drawing, the same components as in FIG. 1, FIG. 3, FIG. 5, FIG. 10, FIG. 11 and FIG. 13 are denoted by the same reference numerals and explanation thereof is omitted.

The present embodiment has a structure of combining plural members having different thermal resistances including the space 13 in Embodiment 1 and the Teflon (registered trademark) stage 14 in Embodiment 2 as shown in FIG. 7.

According to the above structure, accumulation of reaction heat and suppression in radiation of reaction heat can be obtained more effectively.

In FIG. 7, the stage is constructed in the order of the electrostatic adsorption stage 11, the heat-resistant glass stage 12, the Teflon (registered trademark) stage 14 and the space 13 from the top, however, it may be constructed in the order of the electrostatic adsorption stage 11, the Teflon (registered trademark) stage 14, the heat-resistant glass stage 12 and the space 13 from the top and it may combine plural members. Other materials than Teflon (registered trademark) and heat-resistant glass can be combined as long as the total thermal resistance value including the materials is 0.7 [K/W] or more and are hardly corroded with ClF3 gas.

### Embodiment 5

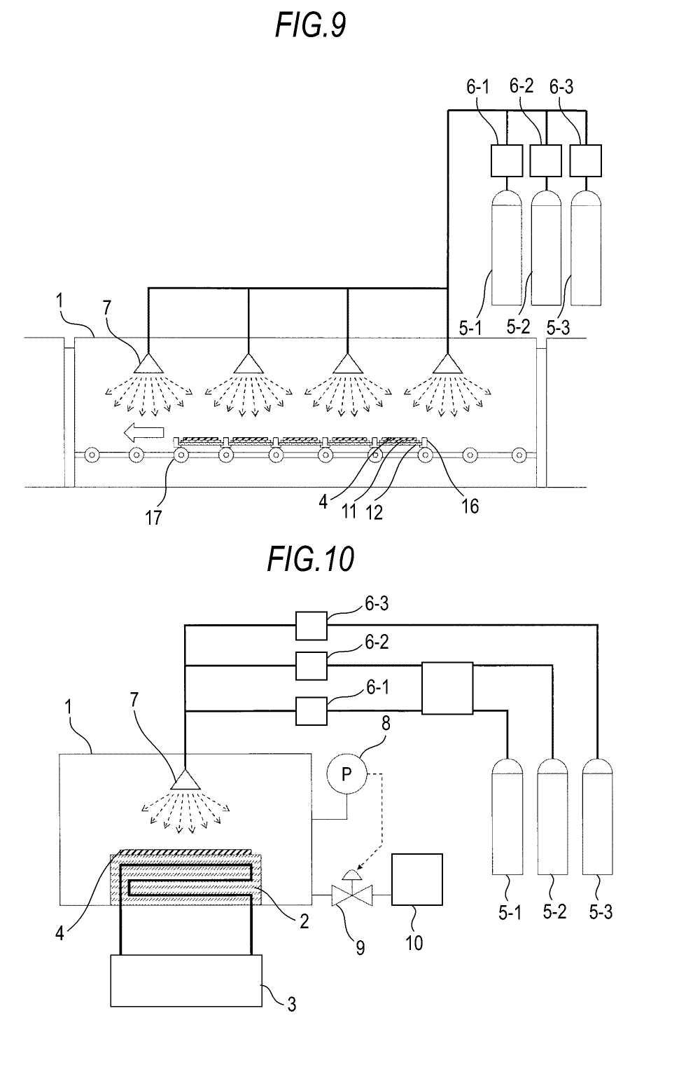

FIG. 8 and FIG. 9 are views showing a dry etching apparatus according to Embodiment 5.

In FIG. 8 and FIG. 9, the same components as in FIG. 1, FIG. 3, FIG. 5, FIG. 7, FIG. 10, FIG. 11 and FIG. 13 are denoted by the same reference numerals and explanation thereof is omitted.

In Embodiment 1, the space 13 is included as shown in FIG. 1. The space 13 is used as the layer for suppressing the radiation of reaction heat. The space 13 can be used as a conveying tray which can process plural substrates as an application as shown in FIG. 3. The heat-resistant glass stages 12 to which the electrostatic adsorption stages 11 are bonded are respectively placed inside respective frames of a SUS tray 16 including plural frames in a lattice state to thereby form the conveying tray. The silicon substrates 4 are placed on plural electrostatic adsorption stages 11 to be adsorbed.

The etching processing is performed while the above-structured conveying tray on which the substrates are placed is conveyed by rollers 17 inside the chamber 1 in which reaction gas is sprayed from, the plural shower nozzles 7 as shown in FIG. 9.

When the silicon substrates placed and adsorbed on the conveying tray are exposed to ClF3 gas and generate heat due to chemical reaction, reaction heat generated on the surfaces of the silicon substrates 4 is accumulated in the electrostatic adsorption stages 11 and the heat-resistant glass stages 12 as in Embodiment 1 while being conveyed as there is space on the back side of the heat-resistant glass stage. On the other hand, space formed by the lattice-state frames blocks the radiation of reaction heat, and neat accumulated in the components of the electrostatic adsorption stage 11 and the heat-resistant glass stage 12 is used as reaction energy to a next chemical reaction.

According to the above structure, it is possible to continuously perform processing of plural substrates without an additional heating mechanism.

When the dry etching apparatus using ClF3 gas having the mechanism of the stage according to the present embodiment is applied, the apparatus capable of manufacturing the substrate on which textures are formed only on one side of the silicon substrate can be provided. Accordingly, it becomes possible to manufacture the back-contact type solar cell by using the silicon substrate with textures formed only on one side by dry etching without ion damage. The technique can be applied to all processing applications using ClF3, not limited to the formation of textures.

What is claimed is:

1. A non-plasma dry etching apparatus comprising:
a processing container;
a nozzle spraying gas into the processing container;
a gas cylinder connected to the nozzle;
a pump discharging gas inside the processing container;
a regulating valve controlling an inside of the processing container to a given pressure; and
a stage arranged inside the processing container and on which a silicon substrate is placed,
wherein the stage is a base formed by plural layers, including an electrostatic chuck layer, a heat-resistant glass layer and a space layer from the side on which the silicon substrate is placed.

2. The non-plasma dry etching apparatus according to claim 1,
wherein the base is arranged on a bottom face of the processing container.

3. The non-plasma dry etching apparatus according to claim 1,
wherein a thickness of the heat-resistant glass layer is 0.5 mm or more and a thickness of the space layer is 0.01 mm or more.

4. The non-plasma dry etching apparatus according to claim 1,
wherein a thickness of the heat-resistant glass layer is 2 mm or more and a thickness of the space layer is 2 mm or more.

5. The non-plasma dry etching apparatus according to claim 1,
wherein the space layer is formed by a member made of Teflon (registered trademark).

6. The non-plasma dry etching apparatus according to claim 1,
wherein the space layer is a thermal contact resistance portion of the base and the heat-resistant glass layer,

7. The non-plasma dry etching apparatus according to claim 6,
wherein the thermal contact resistance portion is the heat-resistant glass layer or the base, in which a surface roughness thereof is Ra=6.3 or more in JIS notation.

8. The non-plasma dry etching apparatus according to claim 1,
wherein the heat-resistant glass layer is formed by plural layers including Teflon (registered trademark).

9. The non-plasma dry etching apparatus according to claim 1,
wherein the total thermal resistance value of the electrostatic chuck layer, the heat-resistant glass layer and the space layer is 0.7 K/W or more.

10. The non-plasma dry etching apparatus according to claim 1,
wherein the total thermal resistance value of the electrostatic chuck layer, the heat-resistant glass layer and the space layer is 5 K/W or more.

11. A non-plasma dry etching apparatus comprising:
a tray having frames;
heat-resistant glass placed on the frames; and
electrostatic adsorption stages bonded on the heat-resistance glass,
wherein plural substrates are placed on stages formed by the above components to be exposed, to chlorine trifluoride gas and etched.
